(19) United States
(12) Patent Application Publication
(10) Pub. No.: US 2024/0395325 A1
(43) Pub. Date: Nov. 28, 2024

(54) METHOD AND APPARATUS OF MEMORY ARRAY DEVICE WITH LOW ARCING RISK

(71) Applicant: Micron Technology, Inc., Boise, ID (US)

(72) Inventors: Shyam Surthi, Boise, ID (US); James E. Davis, Meridian, ID (US); Kenneth W. Marr, Boise, ID (US)

(21) Appl. No.: 18/647,354

(22) Filed: Apr. 26, 2024

Related U.S. Application Data
(60) Provisional application No. 63/469,034, filed on May 25, 2023.

(51) Int. Cl. G11C 16/04; H01L 23/528; H10B 41/10; H10B 41/35; H10B 43/10; H10B 43/35; H10B 99/00

(52) U.S. Cl. CPC G11C 16/0483; H01L 23/5283; H10B 41/10; H10B 41/35; H10B 43/10; H10B 43/35; H10B 99/16

(57) ABSTRACT

A semiconductor device including a substrate; a substrate; a memory array disposed on the substrate, the memory array including one or more memory planes, and a plurality of source region contact (SRC) nodes that are disposed on a backside surface of corresponding one of the one or more memory planes and above the substrate; a plurality of high-voltage (HV) diodes that are disposed in the substrate and that are connected to corresponding SRC nodes, the HV diodes including a first type dopant material; and a plurality of highly doped regions that are disposed in the substrate and that include a second type dopant material, each of the plurality of highly doped regions including a plurality of local maximum doping regions that are vertically aligned under a frontside surface of the substrate.

### CROSS-REFERENCE TO RELATED APPLICATION(S)

The present application claims priority to U.S. Provisional Patent Application No. 63/469,034, filed May 25, 2023, the disclosure of which is incorporated herein by reference in its entirety.

### TECHNICAL FIELD

The present disclosure generally relates to memory array device, and more particularly relates to mitigating arcing risk during fabrication of memory array device for wafer-on-wafer (WOW) packaging of semiconductor device.

### BACKGROUND

Fabrication of microelectronic devices such as high-density memory devices generally include bonding a wafer, e.g., a complementary metal-oxide-semiconductor (CMOS) wafer, to a memory array wafer to form the WOW packaging. The CMOS wafer and the memory array wafer can be further mounted on a package substrate or a carrier wafer and encased in a protective covering. The CMOS wafer may include integrated circuitry with a high density of very small components including processor circuits, imager devices, string drivers, and/or high voltage (HV) circuits. On the other hand, the memory array wafer may include memory arrays including NAND flash memory arrays, dynamic random-access memory (DRAM) arrays, and/or phase change memory (PCM) arrays, the memory arrays being connected to the HV circuits of the CMOS wafer for data signal and control signal transition. Conventional processes for bonding the CMOS wafer and the memory array wafer include electrically coupling/routing of SRC nodes of the memory array to HV diodes that are capable of withstanding high operation voltages. In addition, a heavily doped region can be fabricated in a substrate of the memory array wafer to dissipate charges built up thereon during the processing of the memory array wafer.

### BRIEF DESCRIPTION OF THE DRAWINGS

FIG. 1 depicts a schematic view of a semiconductor device including HV diodes routed to memory array SRC nodes in accordance with embodiments of the present technology.

FIG. 2 depicts a schematic view of a memory array device including HV diodes routed to memory array SRC nodes and a highly doped region in accordance with embodiments of the present technology.

FIG. 3 depicts a schematic view of a memory array device including HV diodes routed to memory array SRC nodes and a plurality of local maximum doping regions in accordance with embodiments of the present technology.

FIGS. 4A and 4B depicts cross-sectional and plan-view schematic views of a memory array device including HV diodes and a plurality of local maximum doping regions in accordance with embodiments of the present technology.

FIG. 5 depicts schematic views of a memory array device layout including HV diodes and local maximum doping regions according to embodiments of the present technology.

FIG. 6 depicts a schematic view of another memory array device layout including HV diodes and local maximum doping regions according to embodiments of the present technology.

FIGS. 7A through 7C illustrate stages of processing a memory array device including HV diodes and a plurality of local maximum doping regions according to embodiments of the present technology.

FIG. 8 is a flow chart illustrating a method of processing a plurality of local maximum doping regions in a memory array device according to embodiments of the present technology.

FIG. 9 is a schematic view of a system that includes a semiconductor device configured according to embodiments of the presented technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

High density memory devices such as NAND flash memory utilizes WOW bonding scheme, e.g., bonding a memory array wafer to a CMOS wafer, in order to achieve a higher device packaging density and improved performance of the components separately processed in the memory array wafer and the CMOS wafer. In fabrications of traditional NAND flash memory such as CMOS on Array (CuA) scheme, the SRC nodes of the memory array are routed to corresponding HV diodes which are capable of withstanding high operation voltages close to or higher than 30V. Particularly, HV diodes in the CuA fabrication scheme are generally disposed in a substrate of the CMOS wafer and are routed to the SRC nodes of the memory array through multiple metal routing layers disposed between the substrate and the memory array. The HV diodes, however, might be hard to be implemented into the CMOS wafer substrate for WOW bonding schemes including a face-to-face (F2F) WOW hybrid bonding scheme and a face-to-back (F2B) direct bonding scheme. The processing of HV diodes in CMOS wafer substrate for above noted WOW bonding schemes can be complicated and the additional routings in the CMOS wafer may degrade the packaging density and device performance thereon.

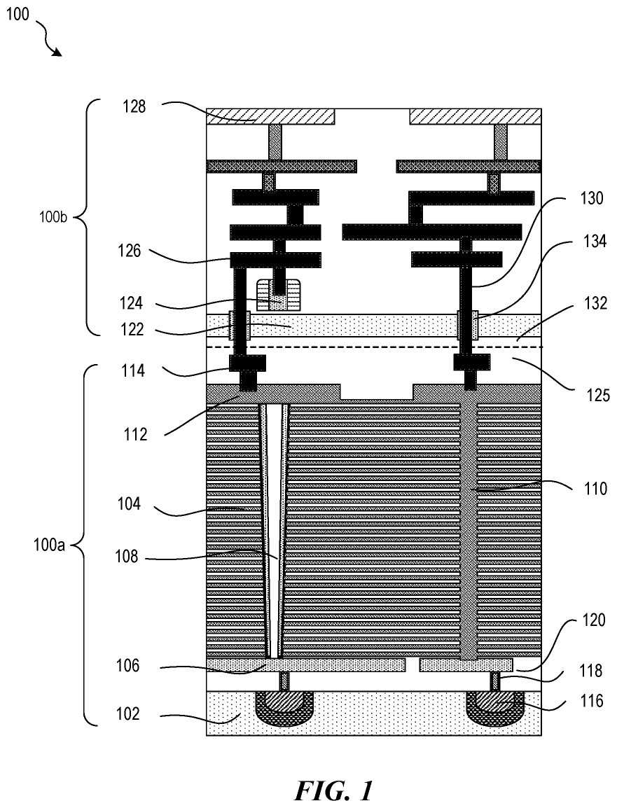

HV diodes can be fabricated and disposed in the memory array wafer for WOW bonding of semiconductor device assembly. For example, HV diodes including a heavily doped region and a lightly doped region can be formed in a substrate of the memory array wafer. The HV diodes can be directly routed to SRC nodes of the memory array through contacts disposed there between. FIG. 1 depicts a schematic view of a semiconductor device 100 including HV diodes 116 routed to memory array SRC nodes 106 in accordance with embodiments of the present technology. The semiconductor device 100 includes a memory device 100a and a logic device 100b, the logic device 100b being bonded to the memory device 100a. Specifically, a backside surface of the Logic device 100b is bonded to a frontside surface of the memory device 100a through a direct WOW bonding technique, e.g., a dielectric-dielectric fusion bonding having strong covalent bonds, to form a F2B WOW bonding as shown in FIG. 1.

In this example, the logic device 100b may include a substrate 122, a plurality of CMOS devices 124 disposed within or above the substrate 122, a plurality of metal routing layers 126, and a plurality of bond pads 128 disposed on a frontside surface of the logic device 100b. The logic device 100b further includes a plurality of deep shallow trench isolation (STI) regions 134 disposed within the substrate 122, and a plurality of contacts 130. Each of the plurality of contacts 130 connects to corresponding one or more of the plurality of metal routing layers 126 and passes through corresponding one of the plurality of deep STI regions 134 for signal transition.

On the other hand, the memory device 100a may include a substrate 102, a memory array 104 disposed above the substrate 102, a plurality of channels 108 and a plurality of deep contacts 110 vertically extending through the memory array 104, and a plurality of land pads 114 each being connected to corresponding one of the plurality of bit lines 122 or deep contacts 110. In this example, each of the plurality of channels 108 connects memory strings from a top tier and a bottom tier. Further, each of the plurality of contacts 130 is connected to corresponding land pads 114 of the memory device 100a, transmitting data/control signals between the CMOS devices 124 and the memory array 104. The memory device 100a includes bit lines 112 disposed above the memory array 104. In addition, the logic device 100b and the memory device 100a include a dielectric layer 132 and a dielectric layer 125 that are disposed on their backside surface and frontside surface, respectively. Here, the dielectric layers 132 and 125 can provide electric isolation among the components disposed in the backside of the logic device 100b and the frontside of the memory device 100a. Further, the direct bonding interface between the logic device 100b and the memory device 100a can be formed by bonding the dielectric layers 132 and 125, including applying heat or compressive pressures there between to form dielectric-dielectric fusion bonds. In this example, the dielectric layers 132 and 125 can be made of materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. Moreover, the fusion bonds formed at the interface of the logic device 100b and the memory device 100a can be oxide-oxide covalent bonds.

In this WOW bonding scheme of semiconductor device 100, the memory device 100a further includes a plurality of HV diodes 116 that are routed to the memory array 104 for SRC nodes protection. As shown in FIG. 1, the plurality of HV diodes 116 can be disposed in the substrate 102, e.g., under a frontside surface of the substrate 102. Each of the plurality of HV diodes 116 can be connected to a corresponding SRC node 106 of the memory array 104 through the contact 118. The memory device 100a also includes a dielectric layer 120 disposed between the SRC nodes 106 and the substrate 102, providing electrical isolation there between. In this example, each of the SRC nodes 106 of the memory array 104 may be connected to one or more dedicated HV diodes 116.

The semiconductor device 100 shown in this example enables transitions of signal/data signals in high voltages (e.g., higher than 30V) from the CMOS devices 124 to corresponding SRC node 106 of the memory array 104. Specifically, the configuration of the HV diodes 116, i.e., disposing in the substrate 102 of the memory array 104 and being directly connected to corresponding SRC nodes 106, avoids complex routing to the logic device 100b in the WOW bonding. In addition, the HV diodes 116 can withstand a high voltage, e.g., close to or higher than 30V, in order to effectively protect the SRC nodes 106 in the semiconductor device 100. In this example, the plurality of HV diodes 116 as well as the plurality of SRC nodes 106 are disposed closer to the memory array 104 in comparison to the fusion bonding interface. In this semiconductor device 100, each of the logic device 100b and the memory device 100a can be processed separately. Particularly, the plurality of HV diodes 116 can be fabricated on the substrate 102 prior to the memory array 104. In this example, the fabrication of HV diodes in the memory array wafer avoids complex routing in the CMOS wafer and provides flexibilities in the locations and numbers of HV diodes corresponding to the SRC nodes of the memory array.

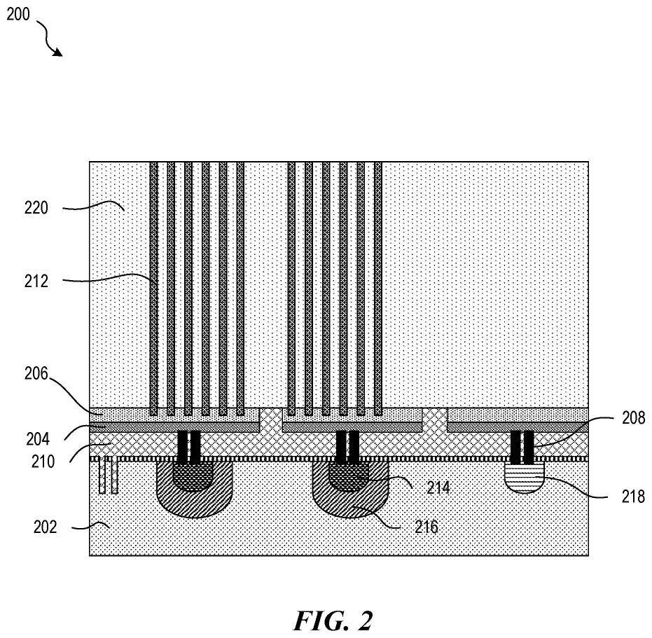

During the fabrication of the high-density memory devices, electric charges may be accumulated on the memory array device and the HV diodes may not be sufficient to dissipate the charge. In particular, the accumulated charges need to be dissipated through a low resistance path to prevent arcing on the memory wafers and/or damaging of manufacturing tools. The arcing risk can be extremely high during a high bias etching process to form high aspect ratio pillars in memory arrays. FIG. 2 illustrates a schematic view of a memory array device 200 including HV diodes routed to memory array SRC nodes and an additional highly doped region 218 to dissipate accumulated charges on the memory array device 200. The highly doped region 218 may have a doping level higher than the substrate 202, e.g., ranging from 1×10¹⁹ ions·cm⁻² to 1×10²¹ ions·cm⁻². In this example, HV diodes can be fabricated in the substrate 202 of the memory array device 200. Specifically, N type dopant materials such as phosphorus, arsenic, and/or antimony can be introduced into a P type doped substrate 202 of the memory array device 200, to form a heavily doped region 214 and a lightly doped region 216 through ion implantation processes. In addition, a dopant material having an opposite type of doping to the heavily and lightly doped regions 214 and 216 can be implanted into the substrate 202 to form the highly doped region 218. Specifically, once the N type heavily doped region 214 and N type lightly doped region 216 are formed, P type dopant materials such as boron and/or gallium can be implanted accordingly. The P type highly doped regions 218 can be disposed in the P type doped substrate 202 to provide an improved contact/lower contact resistance for deep contacts passing through memory array of the memory array device 200. In one example, boron ions with a doping level close to 2×10²⁰ ions·cm⁻² can be implanted and form local maximum doping region 214.

Besides the HV diodes and local maximum doping region, as shown in FIG. 2, the memory array wafer 200 also includes a dielectric layer 210 deposited on the substrate 202. Conductive materials such as tungsten or copper can be filled into contact holes of the dielectric layer 210 to form the contacts 224, each of which having one end connected to the corresponding heavily doped region 214 of corresponding one of the plurality of HV diodes. In addition, the memory array device 200 includes a memory array 220 having channel lines or contracts 212 vertically passing there through. Moreover, SRC nodes each including a metal layer 206 and a poly silicon layer 204 can be formed above the dielectric layer 210 and under the memory array 220. The poly silicon layer 204 of each of the SRC nodes of the memory array 220 can be connected to another end of corresponding one or more contacts 208. In some other examples, an individual HV diode can be configured to connect to multiple SRC nodes of the memory array 220.

For purposes of determining size and shape of memory cells in the memory array device 200, a high voltage bias etch process, e.g., a reactive ion etch (RIE) process may be employed to create openings in the memory array 220. The creation of pillars 212 may cause arcing, e.g., a breakdown of the reaction gas or dielectric materials in the processing equipment during the high bias etch process. In this example, implementing the local maximum doping region 218 helps to dissipate charges through the substrate 202 to reduce the arcing risk but may not be enough. In fabricating advanced memory devices including 150s NAND device and 190s NAND device, a current density related to the arcing may be as high as 2 mA/cm² to 4 mA/cm². For those applications, the resistance of substrate 202 which includes the local maximum doping region 218 may still be high, being a limit factor to enable the amount of current needed to dissipate charge built up on memory array device during the high voltage bias etch process. Different methodologies and designs of memory array device may be needed to reduce the substrate resistance significantly to reduce the risk of arching during the fabrication process.

To address the above-described challenges and other, the present technology includes a novel process and structure of memory array device for the WOW bonding in semiconductor device fabrication. In particular, the memory array device of the present technology includes a plurality of highly doped regions in the substrate. The plurality of highly doped regions are made of a dopant material having opposite doping type to the HV diodes included in the memory array wafer. Moreover, each of the plurality of highly doped regions includes a plurality of local maximum doping regions that are vertically aligned under a frontside surface of the substrate. The plurality of highly doped regions can be disposed close to or completely surround adjacent HV diodes, reducing the substrate resistance and providing a current dissipation path to accumulated charges caused by the high voltage bias etching process.

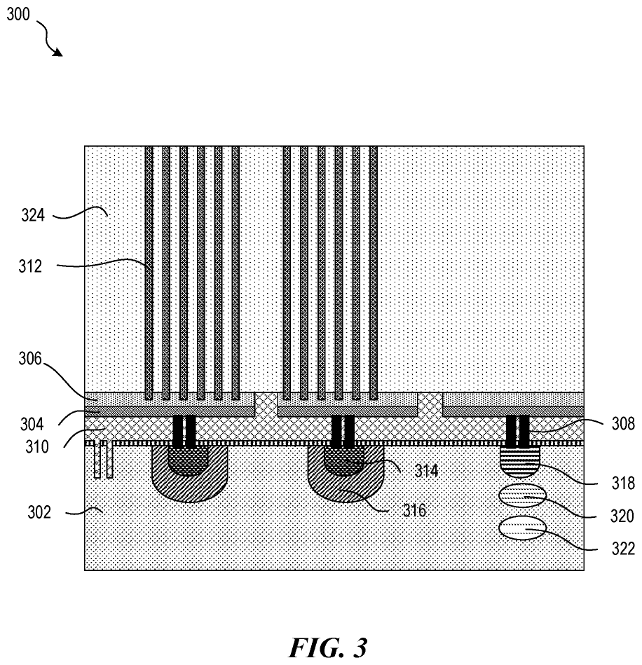

FIG. 3 illustrates a cross-sectional schematic view of a memory array device 300 including a plurality of local maximum doping regions in accordance with embodiments of the present technology. The plurality of local maximum doping regions 318, 320, 322 can be vertically aligned under a frontside surface of substrate 302 of the memory array device 300. As shown, the memory array device 300 also includes one or more HV diodes routed to memory array SRC nodes 306 through contacts 308. Each of the HV diodes is disposed in the substrate 302 and includes a heavily doped region 314 and a lightly doped region 316. In addition, a dielectric layer 310 is disposed above the substrate 302 and under the memory array 324 to provide electrical isolation. The heavily doped region 314 and the lightly doped region 316 can be formed by ion implanting a N type dopant material such as phosphorus, arsenic, and/or antimony into the P type substrate 302. The heavily doped region 314 may have a doping level ranging from 1×10²⁰ ions·cm⁻² to 5×10²⁰ ions·cm⁻². The lightly doped region 316 may have a doping level ranging from 1×10¹⁵ ions·cm⁻² to 1×10¹⁷ ions·cm⁻². In this example, the HV diodes can withstand a high voltage, e.g., close to or higher than 30V, to effectively protect the SRC nodes 306 in a WOW bonding with another CMOS device.

In this embodiment, the plurality of local maximum doping regions 318, 320, and 322 can be formed in the substrate 302 to reduce the substrate resistance. Particularly, the plurality of local maximum doping regions can be formed by sequentially ion implanting a dopant material having an opposite type of doping to the heavily and lightly doped regions 314 and 316, into the P type substrate 302. Each of the plurality of local maximum doping regions may have a doping level ranging from 1×10¹⁹ ions·cm⁻² to 1×10²¹ ions·cm⁻². Here, the local maximum doping regions can be formed by P type dopant materials such as boron and/or gallium. Each of the plurality of local maximum doping regions may have a thickness ranging from 100 nm to 1 μm. In this example, a minimum distance from the plurality of local maximum doping regions (e.g., 318, 320, and 322) to lightly doped region 316 of adjacent HV diode may be needed, e.g., close to or larger than 1 μm to provide enough margin to sustain an applied high voltage (e.g., close to or higher than 30V). Further, the location of the plurality of local maximum doping regions 318, 320, and 322 may vary. For example, they can be disposed toward the memory array plane edges or distributed throughout the memory array planes.

As shown in FIG. 3, the plurality of local maximum doping regions 318, 320, and 322 may have different doping levels. For example, the doping level of local maximum doping region 318 may be the highest and that of the local maximum doping region 322 may be the lowest. Ion implantation process conditions including ion energy, ion dose, implantation angle, implantation temperature, and implantation time can be adjusted to achieve various doping levels of the plurality of local maximum doping regions 318, 320, and 322. For example, an ion beam with a lower acceleration voltage and a higher dose level can be implanted into the substrate 302 through its frontside surface to form the local maximum doping region 322. In comparison, another ion beam with a larger acceleration voltage and a lower dose level can be implanted into the substrate 302 through the frontside surface to form the local maximum doping region 322. In some other embodiments, the memory array device 300 may include a plurality of highly doped regions in the substrate 302, each highly doped region including the plurality of local maximum doping regions 318, 320, and 322 that are vertically aligned. Here, each of the plurality of highly doped regions may have a doping level higher than the substrate 302, e.g., ranging from 1×10¹⁹ ions·cm⁻² to 1×10²¹ ions·cm⁻².

In some embodiments, the plurality of local maximum doping regions 318, 320, and 322 can be doped along a same path, e.g., through a location on the frontside surface of the substrate 302 and into the substrate 302. The dopant profile may be partially overlapped along the doping path. In some embodiments, there are transitional regions vertically disposed among the plurality of local maximum doping regions 318, 320, and 322, the transitional regions having doping levels lower than adjacent local maximum doping regions, e.g., having a doping level ranging from 1×10¹⁴ ions·cm⁻² to 1×10¹⁶ ions·cm⁻². Moreover, depending on patterning processes involved, the plurality of local maximum doping regions 318, 320, and 322 may have various shapes along the horizontal plane including a circular shape, an oval shape, a square shape, and/or a rectangular shape. In addition, each of the plurality of local maximum doping regions may have a circular or a rectangular ring shape in a horizontal plane and completely surrounds adjacent HV diodes in the memory array device. In some embodiments, the memory array device 300 may include two local maximum doping regions that are vertically aligned below the frontside surface of the substrate 302, wherein a first local maximum doping region is disposed above a second local maximum doping region. The first local maximum doping region may have a doping level higher than the second local maximum doping region. In some other embodiments, the memory array device 300 may have more than three local maximum doping regions that are vertically aligned under the frontside surface of the substrate 302. In some other embodiments, the heavily doped region 314 and the lightly doped region 316 may be made of P-type dopant materials. In comparison, the plurality of local maximum doping regions may be made of N-type dopant materials.

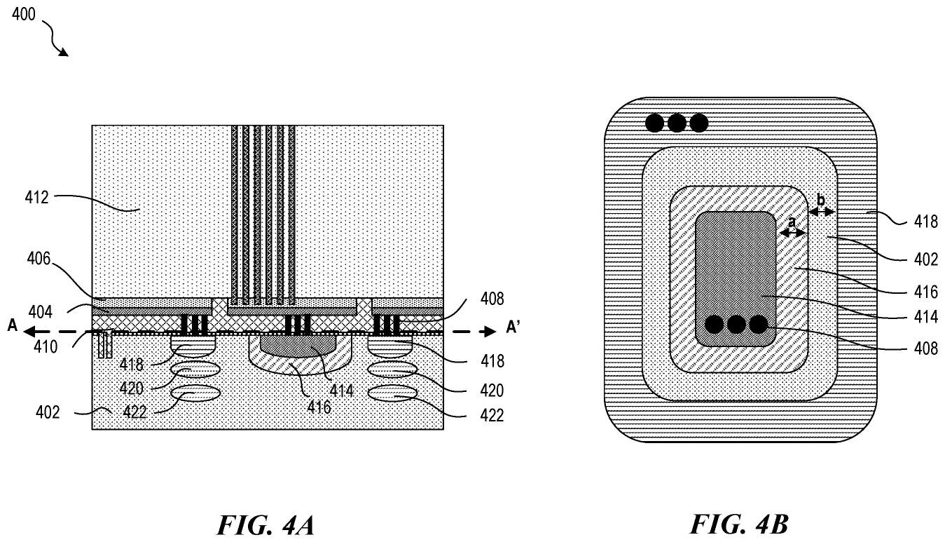

Besides the plurality of local maximum doping regions implemented into the memory array device, a layout of the memory array device can also be adjusted to have the HV diodes to be surrounded by the plurality of local maximum doping regions. This configuration can help ensure sufficient current flow path for dissipating charges accumulated on the memory array device. For example, FIGS. 4A and 4B depict schematic cross-sectional and plan views of a memory array device 400 including a HV diode 415 and a plurality of local maximum doping regions 418, 420, and 422 that surround the adjacent HV diode 415. In this example, the HV diode 415 can be disposed under the frontside surface of substrate 402 of the memory array device 400. The HV diode 415 includes a lightly doped region 416 and a heavily doped region 418 embedded therein. In this example, the heavily doped region 414 may have a doping level ranging from 1×10²⁰ ions·cm⁻² to 5×10²⁰ ions·cm⁻², and the lightly doped region 416 may have a doping level ranging from 1×10¹⁵ ions·cm⁻² to 1×10¹⁷ ions·cm⁻². The HV diode is connected to the SRC nodes 406 of the memory array 412 through contacts 408. The SRC nodes 406 may also include a poly silicon layer 404 and is isolated from the substrate 402 by a dielectric layer 410.

As shown in FIG. 4A, the memory array device 400 includes a plurality of local maximum doping regions 418, 420, and 422 that are vertically aligned under the frontside surface of the substrate 402. In this example, the doping level of each of the local maximum doping regions can be reduced as its location getting deeper. Each of the plurality of local maximum doping regions may have a doping level ranging from 1×10¹⁹ ions·cm⁻² to 1×10²¹ ions·cm⁻². Here, each of the local maximum doping regions can be formed by an opposite type of dopant material to the HV diodes, e.g., P type dopant materials such as boron and/or gallium. In this example, each of the plurality of local maximum doping regions may have a thickness ranging from 100 nm to 1 μm. In some other embodiments, the plurality of local maximum doping regions may have two or more than three doped regions vertically aligned.

In this embodiment and as shown in the plan-view FIG. 4B of the memory array device 400 along the A-A′ plane shown in FIG. 4A, the plurality of local maximum doping regions 418, 420, and 422 can have a ring shape and completely surround the HV diode 415. Moreover, the HV diode 415 and the plurality of local maximum doping region 418 can be connected to the SRC nodes 406 through the contact 408. This configuration of local maximum doping regions in the substrate 402 may ensure a current dissipation path along any directions initiated from the HV diode 415. In particular, a first distance “a” measured between outside edges of the heavily doped region 414 and lightly doped region 416 of the HV diode 415 may range from 0.5 μm to 5 μm, depending on corresponding patterning process prior to ion implanting of the HV diode 415. Moreover, a second distance “b” measured between an outside edge of the lightly doped region 416 and an inner edge of the plurality of local maximum doping region 418 may be close to or larger than 1 μm, depending on specific design run and corresponding patterning process prior to ion implanting of the local maximum doping regions. In this example, each of the first distance and the second distance may be configured to have enough margin, e.g., 1 μm, to make the HV diode 415 capable of sustaining a high voltage close to or higher than 30V and the local maximum doping regions to dissipate charges accumulated on the memory array device 400. Here, the contact 408 can be connected to any edge of the local maximum doping region 418. In some other embodiments, a plurality of contacts 408 can be configured to connect all edges of the high doped region 418 to improve the electrical connection between SRC node 406 and the substrate 402. In some other embodiments, the memory array device 400 may include a plurality of highly doped regions in the substrate 402, each highly doped region including the plurality of local maximum doping regions 418, 420, and 422 that are vertically aligned. Each of the plurality of highly doped regions may have a doping level higher than the substrate 402, e.g., ranging from 1×10¹⁹ ions·cm⁻² to 1×10²¹ ions·cm⁻².

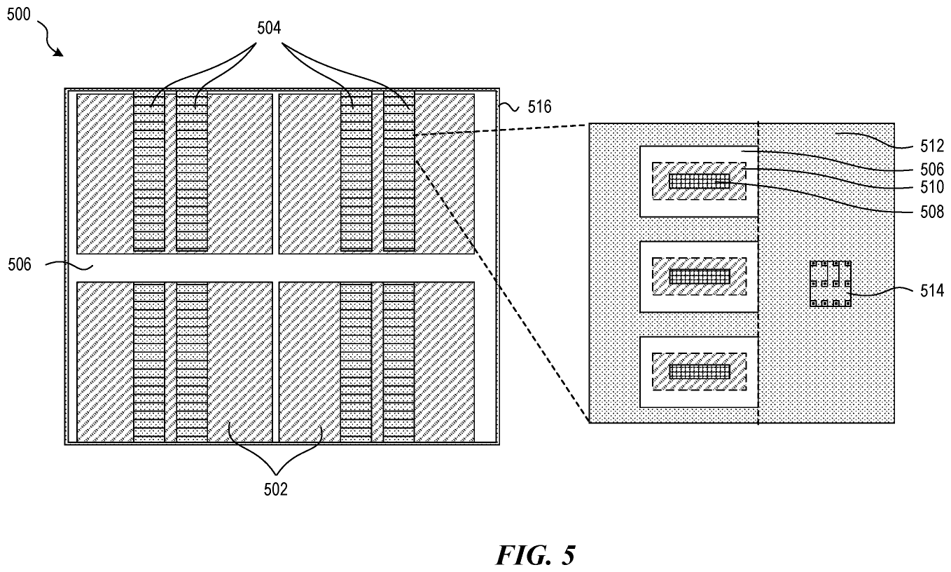

FIG. 5 depicts schematic plan-views of a memory array device 500 including HV diodes 509 and local maximum doping regions 512 and 516, according to embodiments of the present technology. In this example, the memory array device 500 includes a large array of memory planes 502, each one of the memory planes 502 including a plurality of HV diodes 504. As shown in FIG. 5, the memory array of the memory array device 500 can be divided into multiple memory planes to improve the performance and capacity of memory device 500. For example, input/output data can be read and written to various parts of the memory array simultaneously to increase overall speed of the memory array device 500. In this example, each of the memory planes 502 can be separated by a substrate material 506. Specifically, each of the plurality of HV diodes can be surrounded by a plurality of local maximum doping regions vertically aligned in the substrate 506. For example, as shown in FIG. 5, each of the HV diodes 504 is disposed in an individual block on corresponding memory plane 502. In this example, each of the memory planes 502 may include a plurality of SRC nodes disposed there above. Within each individual block, a heavily doped region 508 can be embedded in a lightly doped region 510 to form the HV diode. The lightly doped region can be separated from surrounding local maximum doping region 512 by the substrate material 506. The memory array device 500 also includes a plurality of contacts 514 for electrically connecting local maximum doping regions 512 to corresponding SRC nodes of memory arrays in the memory array device 500. In this example, the heavily doped region 508 and lightly doped region 510 can be made of N-type dopant materials and the local maximum doping regions can be made of P-type dopant materials. In particular, there may be a plurality of local maximum doping regions (e.g., the plurality of local maximum doping regions 318, 320, and 322 described on FIG. 3, or the plurality of local maximum doping regions 418, 420, and 422 of FIG. 4A) that are vertically aligned at the labeled local maximum doping region 512 under a frontside surface of the substrate 506. Moreover, the local maximum doping region may be also disposed at the die (substrate) edge 516 of the memory array device 500.

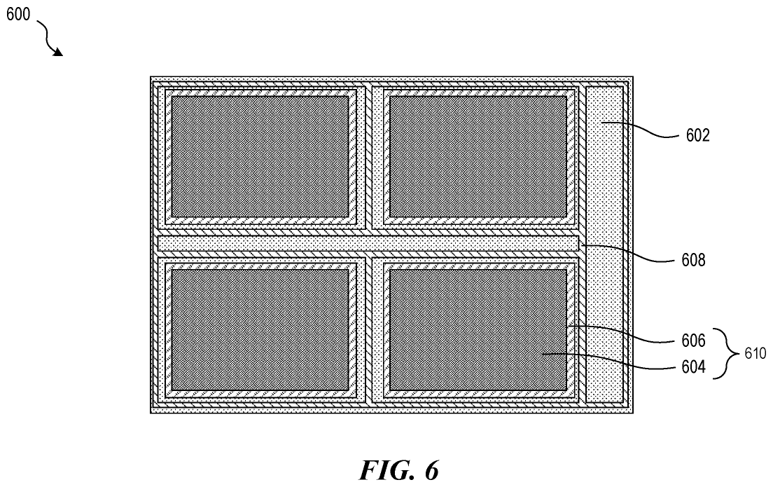

FIG. 6 depicts a schematic plan-view of another memory array device 600 including HV diodes 610 and local maximum doping regions 608 according to embodiments of the present technology. In this example, the memory array device 600 includes multiple memory planes, each memory plane being a local maximum doping region 604 of corresponding HV diode 610. As shown, the heavily doping region 604 is embedded in corresponding lightly doped region 606. Here, the local maximum doping region 608 can be fabricated to surround each of the multiple memory planes and/or is disposed at the die edge of memory device 600. Particularly, the local maximum doping region 608 can be disposed among the memory planes of the memory array device 600. In this example, the heavily doped region 604 and lightly doped region 606 can be made of N-type dopant materials and the local maximum doping regions can be made of P-type dopant materials. In particular, there are a plurality of local maximum doping regions (e.g., the plurality of local maximum doping regions 318, 320, and 322 described on FIG. 3, or the plurality of local maximum doping regions 418, 420, and 422 described on FIG. 4A) that are vertically aligned at the labeled local maximum doping region 608 under a frontside surface of the substrate 602. The surrounding local maximum doping regions 608 can ensure current dissipation of accumulated charges from the memory array device 600. In this example, each one of the memory planes of the memory array device 600 is exclusively connected to one corresponding HV diode 610. In the horizontal plane, the HV diode 610 has a dimension, e.g., a dimension of its lightly doped region 606 in the horizontal plane, similar to the corresponding memory plane.

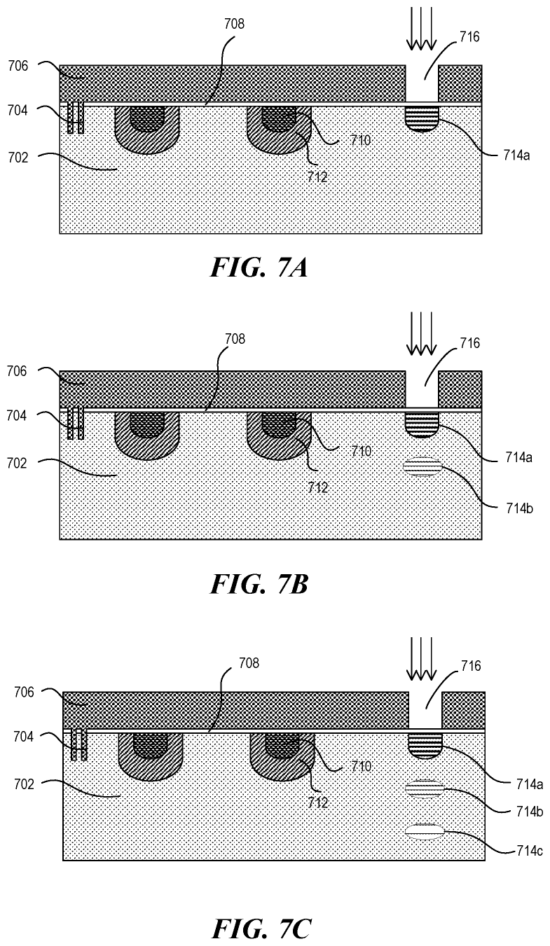

FIGS. 7A through 7C illustrate stages of processing a memory array device 700 including HV diodes and a plurality of local maximum doping regions according to embodiments of the present technology. This process starts from fabricating HV diodes into substrate 702. As shown, a heavily doped region 710 and a lightly doped region 712 can be formed under a frontside surface of the substrate 702 using an ion implantation process. Once the HV diodes are fabricated, a hard mask layer 706 can be coated above the substrate 702. Particularly, a patterning process can be applied on the hard mask layer 706 to form opening 716. The size and location of the opening 716 determine a width and location of the local maximum doping regions. The opening 716 may have various shapes including a circular shape, an oval shape, a square shape, and/or a rectangular shape. In addition, the opening 716 may have a circular or a rectangular ring shape surrounding adjacent HV diodes in the memory array device 700. After the patterning of hard mask layer 706, a dopant material having opposite type of doping in comparison to the heavily doped region 710 and lightly doped region 712 can be implanted into the substrate 702, through the opening 716. The ion implantation process may be controlled to have a higher level of ion dose and lower level of ion energy. For example, 30 KeV boron ions may be implanted into the substrate 702 at room temperature (e.g., close to 300K) to fluences close to 3×10²⁰ ions·cm⁻². In this example, a first local maximum doping region 714a may be formed in the substrate 702 and have a thickness ranging from 100 nm to 1 μm.

In a next step shown in FIG. 7B, a second local maximum doping region 714b can be formed under the local maximum doping region 714a. The second local maximum doping region 714b can be formed through ion implanting dopants having a relatively lower level of ion does and higher level of ion energy, in comparison to that of the first local maximum doping region 714a. For example, 35 KeV boron ions may be implanted into the substrate 702 at room temperature to fluences close to 1×10²⁰ ions·cm⁻². With a higher ion energy, the dopant material can be implanted deeper into the substrate 702 to form the second local maximum doping region 714b. In some embodiments, the second local maximum doping region 714b may have a doping level close to or higher than the first local maximum doping region 714a.

The memory array device 700 may include more than two local maximum doping regions in the substrate 702 for accumulate charge dissipation. For example, as shown in FIG. 7C, a third local maximum doping region 714c can be formed through ion implanting dopants having a relatively lower level of ion does and higher level of ion energy in comparison to that of the second local maximum doping region 714b. For example, 40 KeV boron ions may be implanted into the substrate 702 at room temperature to fluences close to 5×10¹⁹ ions·cm⁻². With a higher ion energy, the dopant material can be implanted even deeper into the substrate 702 to form the third local maximum doping region 714b. In this example, following the shape of opening 716 (e.g., a circular or a rectangular ring shape surrounding adjacent HV diodes), the plurality of local maximum doping regions 714a, 714b, and 714c can have a similar circular or rectangular ring shape that surround adjacent HV diodes in the memory array device 700. In this example, additional processes can be conducted to form SRC nodes and memory array above the substrate 702 to complete the memory array device 700.

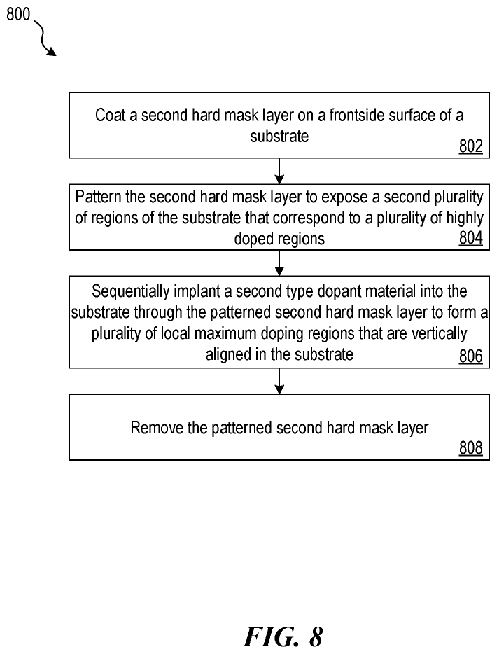

Turning to FIG. 8 which is a flow chart illustrating a method 800 of processing a plurality of local maximum doping regions in a memory array device according to embodiments of the present technology. For example, the method 800 includes coating a second hard mark layer on the frontside surface of the substrate, at 802. For example, after forming a heavily doped and lightly doped regions 710 and 712 by ion implanting a first type dopant material, a patterned first hard mask layer can be removed from the substrate 702 of the memory array device 700. Following that, the second hard mask layer 706 can be coated on the frontside surface of the substrate 702 for processing of the plurality of local maximum doping regions, as described in FIG. 7A.

In addition, the method 800 includes patterning the second hard mask layer to expose a second plurality of regions of the substrate that correspond to the plurality of highly doped regions, at 804. For example, the hard mask layer 706 can be patterned to form one or more openings. As show in FIG. 7A, the opening 716 may have various shapes including a circular shape, an oval shape, a square shape, and/or a rectangular shape. In addition, the opening 716 may have a circular or a rectangular ring shape surrounding adjacent HV diodes in the memory array device 700.

The method 800 also includes sequentially implanting a second type dopant material into the substrate through the patterned second hard mask layer to form the plurality of local maximum doping regions that are vertically aligned in the substrate, at 806. For example, a second type dopant material having opposite type doping to the first type of dopant of HV diodes can be sequentially implanted into various depth of the substrate 702. Each of the ion implantation process may be configured to employee ions having different ion energies. The plurality of local maximum doping regions, e.g., the local maximum doping regions 714a, 714b, and 714c of FIG. 7C, can be vertically aligned in the substrate 702 by aligning the direction of ion plantation processes.

Lastly, the method 800 includes removing the patterned second hard mask layer, at 808. For example, once all of the plurality of local maximum doping regions 714a, 714b, and 714c are formed, the second hard mask layer 706 can be removed from the frontside surface of the substrate 702. Moreover, additional processes can be conducted to form SRC nodes and memory array above the substrate 702 to complete the memory array device 700, as described in FIG. 7C. The memory array device may be further bonded with a CMOS device, as the WOW bonding scheme shown in FIG. 1.

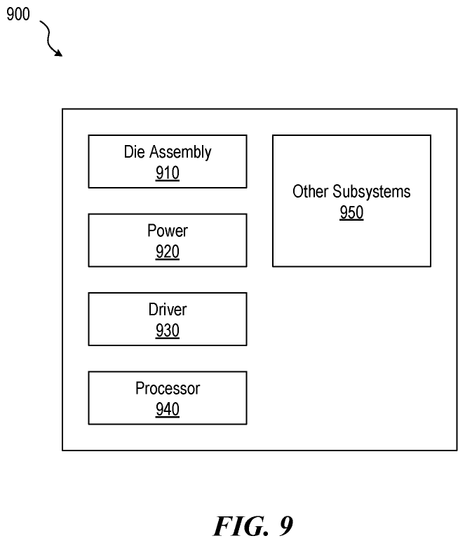

Any one of the semiconductor structures described above with reference to FIGS. 1-8 can be incorporated into any of a myriad of larger and/or more complex systems, a representative example of which is system 900 shown schematically in FIG. 9. The system 900 can include a semiconductor device 910, a power source 920, a driver 930, a processor 940, and/or other subsystems or components 950. The semiconductor device 910 can include features generally similar to those of the semiconductor devices described above and can therefore include HV diodes and local maximum doping regions described in the present technology. The resulting system 900 can perform any of a wide variety of functions, such as memory storage, data processing, and/or other suitable functions. Accordingly, representative systems 900 can include, without limitation, hand-held devices (e.g., mobile phones, tablets, digital readers, and digital audio players), computers, and appliances. Components of the system 900 may be housed in a single unit or distributed over multiple, interconnected units (e.g., through a communications network). The components of the system 900 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a substrate;
a memory array disposed on the substrate, the memory array including:
one or more memory planes, and
a plurality of source region contact (SRC) nodes that are disposed on a backside surface of corresponding one of the one or more memory planes and above the substrate;
a plurality of high-voltage (HV) diodes that are disposed in the substrate and that are connected to corresponding SRC nodes, the HV diodes including a first type dopant material; and
a plurality of highly doped regions that are disposed in the substrate and that include a second type dopant material, each of the plurality of highly-doped regions including a plurality of local maximum doping regions that are vertically aligned under a frontside surface of the substrate.

2. The semiconductor device of claim 1, wherein the plurality of highly doped regions have a ring shape profile in a horizontal plane and surrounds corresponding one or more of the plurality of HV diodes.

3. The semiconductor device of claim 1, wherein each of the one or more memory planes is connected to a group of the plurality of HV diodes, the group of the plurality of HV diodes being surrounded by a corresponding highly doped region.

4. The semiconductor device of claim 3, wherein the plurality of highly doped regions is further disposed at edge region of the substrate.

5. The semiconductor device of claim 1, wherein each of the one or more memory planes is exclusively connected to one corresponding HV diode, the one corresponding HV diode having a dimension, in a horizontal plane, similar to the each of the one or more memory planes, and wherein the plurality of highly doped regions are disposed among the one or more memory planes and at edge region of the substrate.

6. The semiconductor device of claim 1, wherein each of the plurality of HV diodes includes a heavily doped region and a lightly doped region, wherein the heavily doped region is embedded within the lightly doped region.

7. The semiconductor device of claim 1, wherein the first type dopant material is a n-type semiconductor material, and the second type dopant material is a p-type semiconductor material.

8. The semiconductor device of claim 1, wherein doping levels of the plurality of local maximum doping regions are gradually reduced along a direction from the frontside surface to a backside surface of the substrate.

9. The semiconductor device of claim 1, further include transitional regions including the second type dopant material, wherein the plurality of local maximum doping regions are discrete, and the transitional regions are disposed within the substrate and among the vertically aligned plurality of local maximum doping regions.

10. The semiconductor device of claim 1, wherein a doping level of each of the transitional regions is lower than adjacent local maximum doping regions.

11. A semiconductor device, comprising:
a substrate;
a plurality of memory planes that are disposed on the substrate, each one of the plurality of memory planes being connected to one or more high-voltage (HV) diodes that are disposed in the substrate; and
a plurality of highly doped regions that are disposed in the substrate, each surrounding one or more corresponding HV diodes, each of the plurality of highly doped regions including a plurality of local maximum doping regions that are vertically aligned in the substrate.

12. The semiconductor device of claim 11, wherein each one of the plurality of memory planes is exclusively connected to a corresponding HV diode, and wherein the plurality of highly doped regions are disposed among the plurality of memory planes and at edge region of the substrate.

13. The semiconductor device of claim 11, wherein each one of the plurality of memory planes is connected to a group of the one or more HV diodes, wherein the group of the one or more HV diodes are surrounded by a corresponding highly doped region, and wherein the plurality of highly doped regions are disposed at edge region of the substrate.

14. The semiconductor device of claim 13, wherein each of the plurality of highly doped regions and corresponding HV diode are separated by a threshold distance ranging from 1 μm to 10 μm.

15. A method of forming a semiconductor device, comprising:
forming a plurality of high-voltage (HV) diodes in a substrate of the semiconductor device, the plurality of HV diodes including a first type dopant material,
forming a plurality of highly doped regions in the substrate and that include a second type dopant material, each of the plurality of highly doped regions including a plurality of local maximum doping regions that are vertically aligned under a frontside surface of the substrate,
forming a memory device including one or more memory planes, the one or more memory planes including a plurality of source region contact (SRC) nodes disposed on a backside surface of the one or more memory planes and above the substrate, the plurality of SRC nodes being connected to corresponding HV diodes;
bonding a complementary metal-oxide-semiconductor (CMOS) device with the memory device, and
forming interconnects that pass through the CMOS device and into the memory device, the interconnects electrically connecting the CMOS device and the memory device.

16. The method of claim 15, wherein forming the memory device includes dissipating, through the plurality of highly doped regions disposed in the substrate, charges cumulated on the memory device.

17. The method of claim 15, wherein forming the plurality of HV diodes including:
coating a first hard mask layer on a frontside surface of the substrate,
patterning the first hard mask layer to expose a first plurality of regions of the substrate that correspond to the plurality of HV diodes,
implanting a first dopant material into the substrate through the patterned first hard mask layer to form a plurality of first heavily doped regions of the HV diodes,
trimming the patterned hard mask layer to enlarge openings of the patterned hard mask,
implanting the first type dopant material into the substrate through the trimmed hard mask layer to form a plurality of lightly doped regions of the HV diodes, wherein each of the first heavily doped regions is disposed within corresponding lightly doped region, and
removing the patterned first hard mask layer.

18. The method of claim 17, wherein forming the plurality of highly doped regions including:
coating a second hard mask layer on the frontside surface of the substrate,
patterning the second hard mask layer to expose a second plurality of regions of the substrate that correspond to the plurality of highly doped regions,
sequentially implanting a second type dopant material into the substrate through the patterned second hard mask layer to form the plurality of local maximum doping regions that are vertically aligned in the substrate, and
removing the patterned second hard mask layer.

19. The method of claim 18, wherein each of the sequentially implanting creates one of the plurality of local maximum doping regions in the substrate.

20. The method of claim 19, further comprises forming transitional regions including the second type dopant material, the transitional regions being disposed, through the sequentially implanting, within the substrate and among the vertically aligned plurality of local maximum doping regions.
